(19) United States
(12) Patent Application Publication
(10) Pub. No.: US 2003/0052088 A1
(43) Pub. Date: Mar. 20, 2003

(54) Method for increasing capacitance in stacked and trench capacitors

(76) Inventors: Anisul Khan, Sunnyvale, CA (US); Ajay Kumar, Sunnyvale, CA (US); Sharma Pamarthy, Hayward, CA (US); Sanjay Thekdi, Santa Clara, CA (US)

Correspondence Address: APPLIED MATERIALS, INC., 2881 SCOTT BLVD. M/S 2061, SANTA CLARA, CA, 95050, US

(21) Appl. No.: 09/957,000

(22) Filed: Sep. 19, 2001

(51) Int. Cl. H01L 21/3065

(52) U.S. Cl. 216/67; 216/79; 438/719; 438/733

(57) ABSTRACT

Trench and stacked capacitors are commonly used in the construction of DRAMs utilized in electronic devices. Conventional methods of manufacture typically result in capacitor structures having relatively smooth sidewall profiles which are integrated into a capacitor structure. The present invention provides a novel method by which the capacitance density of both trench and stacked capacitors can be increased, without increasing the footprint or depth of the capacitor structure, by increasing the surface area of the sidewall profiles of the capacitor structures using an iterative etch process that comprises an isotropic plasma etching step to achieve an enlarged sidewall profile.

### FIELD OF THE INVENTION

The present invention relates to methods of etching trench and stacked capacitors and more particularly to methods which enhance the surface area etched in the production of a capacitor and, thereby, the capacitance of the capacitor produced.

### BACKGROUND OF THE INVENTION

Dynamic Random Access Memory (DRAM) circuits have become pivotal in the semiconductor industry. The density of DRAM circuits has increased by a factor of four every three years during the past 25 years, and this trend continues today. This remarkable increase in density has been brought about by advances in various areas of processing technology, including lithography, dry patterning, and thin-film deposition techniques, and by improvements in the DRAM architecture that resulting in a more efficient cell utilization. As the lithographic feature size decreases from 0.25 to 0.10 μm, the area of the DRAM cell is expected to decrease by a factor of more than ten.

Since DRAM cells contain a single transistor and capacitor and since each capacitor must be isolated from adjacent capacitors in the array, only a fraction of the cell area can be occupied by the capacitor. The minimum amount of charge that must be stored in the capacitor in order to obtain reliable operation of the DRAM is determined by the sensitivity limits of the sense amplifiers, parasitic capacitances, and alpha-particle considerations. This minimum charge has historically decreased by about a third per generation. Similar decreases in operating voltage are expected for future DRAM generations, so that the required DRAM capacitance will remain nearly constant at 25-30 fF/cell. Achieving the required capacitance density while at the same time maintaining a charge loss of <10% after one second, corresponding to a current density of approximately 1 fA/cell, has become a major challenge in fabricating future generations of DRAM.

Higher capacitance density can be achieved by the use of 1) complex electrode structures providing a large surface area within a small lateral area; 2) thinner capacitor dielectrics; and 3) higher-permittivity capacitor dielectric materials.

The storage part of a DRAM cell is a capacitor in which, typically, the bottom electrode is polycrystalline silicon (polysilicon) or hemispherical grain polysilicon (HSG). Recently, there has been a growing trend towards the use of trench and stacked capacitors in the manufacture of DRAM circuits.

Trench capacitors have been adopted as a means of saving wafer surface area and are implemented by creating a capacitor in a trench etched vertically into a wafer surface. The trenches are etched to form sidewalls, which are oxidized to form the dielectric element of a capacitor, and the center of the trench is then filled with deposited polysilicon. The final structure is “wired” from the surface, with the silicon and polysilicon serving as the two electrode elements of a capacitor with the silicon dioxide dielectric between them.

Stacked capacitors are another approach to space saving where conserving wafer surface area is desired. In this alternative, capacitors are built on and above the wafer surface instead of in a trench buried in the wafer as is the case with a trench capacitor.

With the need for smaller and smaller devices, the space available in devices for creating capacitors is limited, requiring innovation in creating the required capacitance in a DRAM while reducing the space utilized.

### SUMMARY OF THE INVENTION

The above and other difficulties are overcome by the present invention. In summary, the present invention provides a method for increasing the surface area etched in the production of both trench and stacked capacitors. As a result, the capacitance density of the capacitors produced in accordance with the present invention can be increased without an increase in the footprint or depth of the capacitor.

According to one aspect of the present invention, a method for etching a portion of the structure of a capacitor within a substrate is provided that comprises (a) providing a masked substrate (e.g., a single crystal silicon substrate), comprising a patterned resist layer over a silicon substrate, with the patterned resist layer having at least one aperture formed therein; and (b) forming a portion of a capacitor structure in the silicon substrate through the one or more apertures provided by conducting an iterative plasma etching scheme which comprises iteratively exposing the silicon substrate to at least one isotropic plasma step until a desired etch depth is achieved and thereby creating an etched surface having an undulating, semi corrugated profile. Typically, the etched portion of the capacitor structure ranges from 1-2.0 microns in vertical dimension in the case where a stacked capacitor is produced, and up to 10 microns when a trench capacitor is produced.

In some embodiments of the invention, the iterative etching scheme comprises performing (1) an anisotropic etch of the substrate followed by (2) an isotropic etch of the substrate, or vice versa.

In other embodiments, the iterative etching scheme comprises performing (1) an anisotropic etch of the substrate followed by (2) a passivation deposition step. For example, a method for etching the structure of a capacitor within a substrate can be provided that comprises: (a) providing a masked substrate, comprising a patterned resist layer over a silicon substrate, the patterned resist layer having at least one aperture formed therein; and (b) forming a portion of a capacitor structure in the silicon substrate through the one or more apertures by an iterative plasma etching step comprising alternately exposing the substrate to (1) a first plasma step adapted to isotropically etch the substrate and (2) subsequently exposing the substrate to a second plasma step adapted to deposit a passivating layer on the substrate, with the etching and deposition steps being repeated until a desired etch depth is achieved, thereby creating an etched surface having a semi corrugated profile.

The above advantages and embodiments of the present invention will become immediately apparent to those of ordinary skill in the art upon reading the detailed description and claims to follow.

### BRIEF DESCRIPTION OF THE DRAWINGS

FIG. 1 is a schematic diagram depicting an exemplary etching system that may be used in connection with embodiments of the present invention.

FIG. 2 is a schematic diagram depicting a cross-sectional view of a trench capacitor structure created by conventional methods.

FIG. 3 is a schematic diagram depicting a cross sectional view of a stacked capacitor structure created by conventional methods.

FIG. 4 is a schematic diagram depicting the structure of a stacked capacitor in accordance with the present invention.

FIGS. 5-7 are schematic diagrams depicting the development of a capacitor structure in accordance with an embodiment of the present invention.

FIG. 8. depicts a schematic diagram detailing a sidewall profile in accordance with an embodiment of the present invention.

FIG. 9 depicts a schematic diagram of a capacitor in accordance with the method of the present invention.

FIGS. 10-12 are schematic diagrams depicting the development of a capacitor structure in accordance with an additional embodiment of the present invention.

FIG. 13 depicts a schematic diagram of a sidewall profile of a substrate prepared in accordance with the method of the present invention.

FIG. 14 depicts a schematic diagram outlining the method of a first embodiment of the present invention.

FIG. 15 depicts a schematic diagram outlining the method of a second embodiment of the present invention.

### DETAILED DESCRIPTION OF THE PREFERRED EMBODIMENTS

It is worthy to note that any reference herein to “one embodiment” or “an embodiment” means that a particular feature, structure, or characteristic described in connection with the embodiment is included in at least one embodiment of the invention. The appearances of the phrase “in one embodiment” in various places in the specification are not all necessarily referring to the same embodiment. Moreover, as used in this specification and the appended claims, the singular forms “a” “an”, and “the” include plural referents, unless the context clearly dictates otherwise.

All percentages (%) listed for gas constituents are % by volume, and all ratios listed for gas constituents are ratio by volume.

The various embodiments of the present invention include inter alia an etch process which creates an undulating, semi-corrugated etched sidewall profile on the surfaces of the structures corresponding to portions of trench and stack capacitors. The undulating, semi-corrugated surface etched on the sidewall surfaces of the structures during manufacture ultimately corresponds to an increase in the effective surface area of trench and stack capacitors, relative to that achieved by conventional methods. This increase in effective surface area increases the capacitance density of the trench or stack capacitor structure produced without resorting to a corresponding increase in the depth or aspect ratio of the resulting capacitor.

Capacitance is directly proportional to the area of the two electrodes or plates that comprise a capacitor. Thus, an increase in the capacitance of a capacitor can be effected by increasing the surface area of the plates. The methods of the present invention utilize techniques including isotropic etching and anisotropic etching and deposition techniques to create etched trench or stack capacitor surfaces with areas that are greater than those yielded by conventional manufacturing methods, thereby creating capacitors with increased capacity relative to those created by conventional methods.

The etching and deposition processes of the present invention can be carried out in a number of plasma systems. One such system is disclosed in U.S. Pat. No. 6,074,954, the entire disclosure of which is incorporated by reference. It should be noted, however, that other plasma systems, including other inductively coupled plasma systems are equally suitable.

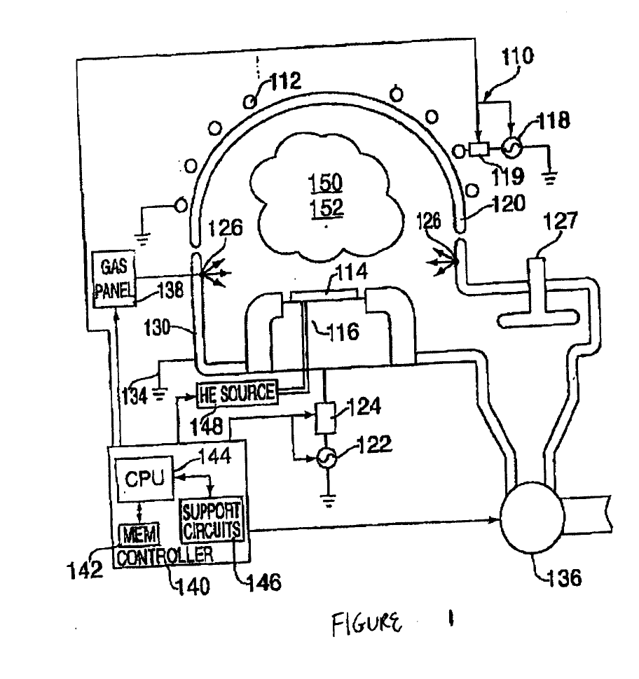

FIG. 1 depicts a schematic of a decoupled plasma source (DPS) etch process chamber 110, that comprises an inductive coil antenna segment 112, positioned exterior to a dielectric, dome shaped ceiling 120. The antenna segment 112 is coupled to a radio-frequency (RF) generator 118 that is generally capable of producing a 200 W-3000 W RF signal having a tunable frequency that is typically about 12.56 MHz. This first RF source 118 is coupled to the antenna segment 112 via a matching network 119. The process chamber 110 also includes a substrate support pedestal (cathode) 116 that is coupled to a second RF source 122 generally capable of producing a 1 W-500 W RF signal having a frequency that is typically approximately 400 KHz. The second RF source 122 is coupled to the substrate support pedestal 116 through a matching network 124. Hereinafter, the first and second RF sources 118 and 122 will be referred to as an RF source generator 118 and an RF bias generator 122 respectively.

Chamber 110 also contains a conductive chamber wall 130 that is coupled to an electrical ground 134. A controller 140 comprising a Central Processing Unit (CPU) 144, a memory 142, and support circuits 146 for the CPU 144 is coupled to the various components of the DPS process chamber 110 to facilitate control of the etch process.

In operation, a semiconductor substrate 114 is placed on the substrate support pedestal 116 and gaseous components are supplied from a gas panel 138 to the process chamber 110 through inlets 126 to form a gaseous mixture 150. The gaseous mixture 150 is ignited into a plasma 152 in the process chamber 110 by applying RF power from the RF source and bias generators 118 and 122, respectively, to the antenna segment 112 and the substrate support pedestal 116. The pressure within the interior of the process chamber 110 is controlled using a throttle valve 127 situated between the chamber 110 and a vacuum pump 136. The temperature at the surface of the chamber wall 130 is controlled using liquid containing conduits (not shown) that are located within the walls 130 of the chamber 110. For example the walls 130 can be maintained at about 65 degrees Celsius during processing.

The temperature of the substrate 114 is controlled by stabilizing the temperature of the support pedestal 116 and providing He gas from a He source 148 to channels formed between the back of the substrate 114 and grooves (not shown) on the surface of support pedestal 116 facilitating heat transfer between the substrate 114 and support pedestal 116. During the etch process, the substrate 114 is gradually heated by the plasma 152 to a steady state temperature. Typically substrate 114 is maintained in a temperature range of between about −40 to about 60 degrees Celsius with a preferred operating range of about 15 to about 20 degrees Celsius.

The CPU 144 controls the chamber as described above and may be any general purpose computer for industrial use and adapted to control the various chamber components. The memory 142 is coupled to the CPU 144 and may be one or more of readily available memory devices such as random access memory (RAM), read only memory (ROM), floppy disk drive, hard disk, or any other form of local or remote digital storage means. The support circuits 146 are coupled to the CPU 144 for supporting the processor in a conventional manner. Support circuits 146 include cache, power supplies, clock circuits, input and output circuitry and the like.

One particularly preferred system is the DPS Centura® etch system offered by Applied Materials, Inc., of Santa Clara Calif.

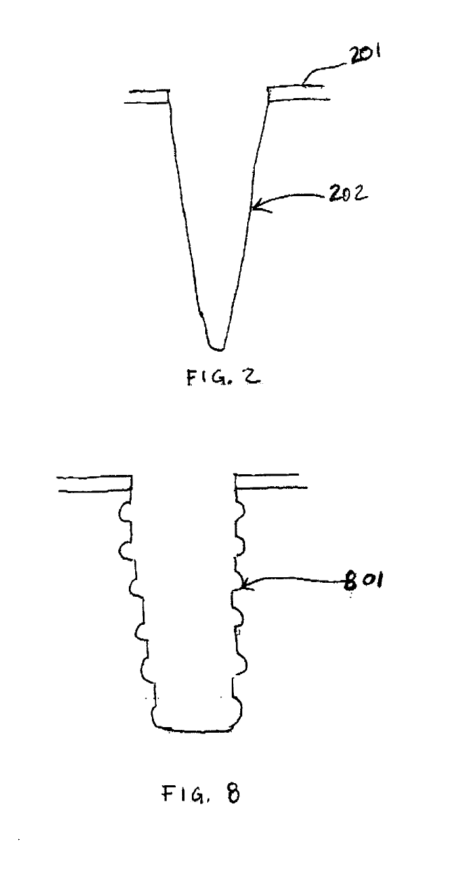

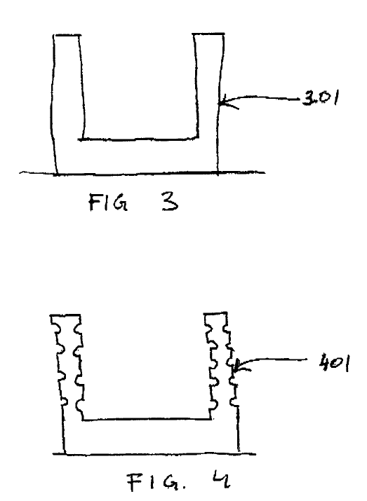

In conventional applications, the structure of trench and stacked capacitors comprise relatively smooth sidewalls that are etched as part of the manufacturing process. The profile of the structure associated with a conventional trench capacitor is shown in FIG. 2. The structure comprises a surface mask 201 that has an aperture through which etching is performed. Etch chemistry is selected such that the profile of the trench sidewall 202 remains relatively smooth from the surface mask and through the depth of the etched trench. Similarly, the structure associated with a stacked capacitor produced in conventional fashion is depicted in FIG. 3. As is depicted therein, the profile of the sidewall 301 is substantially planar and smooth.

In contrast to the structure of the stacked capacitor shown in FIG. 3, the structure associated with a stacked capacitor in accordance with the present invention as depicted in FIG. 4 comprises an undulating, semi-corrugated sidewall profile 401. The undulating, semi-corrugated sidewall profile 401 results in an increased sidewall surface area as compared to the smooth sidewall profile 301 in FIG. 3.

In a first embodiment of the present invention, the undulating, semi-corrugated sidewall profile 401 is achieved with a combination of etch chemistries used to generate specific plasma types to which a substrate is exposed. In particular, the substrate is exposed to a first plasma that etches the substrate anisotropically. The substrate is then exposed to a second plasma that results in an isotropic etch of the substrate. These etch chemistries are known in the art.

In one specific embodiment, this iterative etch process is performed utilizing an etch system like that described above. Referring again to FIG. 1, the semiconductor substrate 114 is placed on the substrate support pedestal 116 and initial gaseous components comprising plasma source gases appropriate for anisotropic etching, for example, SF₆ and HBr and O₂ can be supplied from gas panel 138 to the process chamber 110 through inlets 126 to form a gaseous mixture 150. For example, the SF₆, HBr and O₂ flow rates can each be about 50 sccm. The gaseous mixture 150 is ignited into a plasma 152 in the process chamber 110 by applying RF power preferably in the region of a 1000 W of source power and 20 W bias power from the RF source and bias generators 118 and 122, respectively, to the antenna segment 112 and the substrate support pedestal 116. The pressure within the interior of the process chamber 110 is controlled between 10-200 mtorr and preferably in the region of 30 mtorr, using the throttle valve 127 situated between the chamber 110 and the vacuum pump 136. The combination of plasma source gases yields a plasma that anisotropically etches the substrate, typically at a rate of approximately 1-3 microns/minute. The result of an initial anisotropic etch in accordance with the present invention is shown in FIG. 5. As is depicted therein, the anisotropic etch step yields substantially smooth sidewalls 401 and a substantially vertical etch to a desired depth. The vertical sidewalls are due in part to a passivation layer that is provided during the course of this process step.

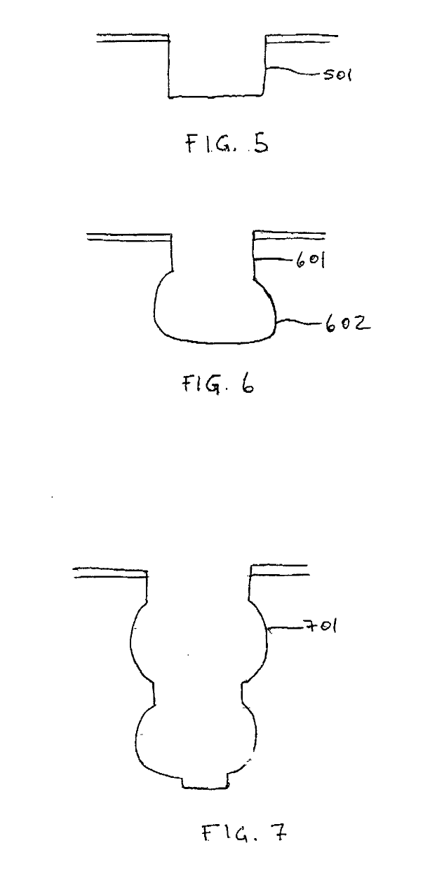

Once the desired degree and depth of anisotropic etching is achieved, the plasma source gases are replaced by a source gas appropriate for isotropic etching, for example, a source gas preferably comprising one of SF₆, Cl₂, NF₃, and CF₄, with SF₆ source gas being a more preferred choice. For example, with an SF₆ source gas flow rate of about 100 sccm, the source gas is ignited into a plasma by applying RF power preferably in the region of 1000 W of source power and 10 W bias power. The pressure within the interior of the process chamber is controlled between 10-200 mtorr and preferably in the region of 20 mtorr. The combination of plasma source gases yields a plasma that anisotropically etches the substrate, typically at a rate of approximately 1-5 microns/minute. The SF₆ plasma source gas produces a plasma that etches the substrate isotropically, and vertically continues the etching begun during the anisotropic etch step. The resultant combination of the anisotropic etch step and the isotropic etch step is illustrated in FIG. 6. As is depicted therein, the isotropic etch step achieves etching in all directions and combines with the portion of the substrate previously etched anisotropically to yield a vertical “shaft-like” component 601 extending into a “balloon-shaped” segment 602 formed by the isotropic etching step.

In accordance with the method of the present invention, the iterative process of alternating anisotropic etching with isotropic etching to achieve an undulating, semi-corrugated sidewall is repeated as necessary until a desired etch depth is reached. Referring now to FIG. 7, depicted therein is a schematic diagram detailing the resultant sidewall profile 701 of a substrate after two repetitions each of alternating anisotropic and isotropic etch steps.

Referring now to FIG. 8, this figure depicts an undulating, semi-corrugated sidewall profile 801 of a portion of a trench capacitor structure that has been etched in accordance with the present invention. When compared with the sidewall structure 202 of FIG. 2, it is readily discernible to one skilled in the art that the undulating, semi-corrugated sidewall profile 801 of FIG. 8 provides a larger surface area than the smooth sidewall profile 202 of FIG. 2, while retaining the same overall depth of the structure of FIG. 2.

Thus, when a capacitor structure is etched in accordance with the method of the present invention, it affords a larger surface area per unit depth than a capacitor constructed in conventional fashion. The larger surface area translates to increased capacitance density when the structure is integrated into a completed capacitor. A trench capacitor utilizing a structure provided by the method of the present invention is shown in FIG. 9.

As is depicted therein, a capacitor 901 includes a dielectric element 903, which is typically formed by oxidizing the substrate to form silicon dioxide. The center of the etched and oxidized undulating, semi-corrugated trench is then filled with deposited polysilicon 904 which acts as the second “plate” of the capacitor, while an outer region of the etched silicon substrate 905 acts as a first “plate” of the capacitor. Metal contact 902 is connected to polysilicon 904. Alternatively, contact 902 can be formed of doped polysilicon. Hence, the final structure is “wired” from the surface with the etched silicon substrate 905 and the deposited polysilicon 904 serving as the two electrode elements of the capacitor with the silicon dioxide 903 dielectric between them.

It should be noted that the order of the above iterative etch sequence can be reversed and alternatively be performed by first etching the silicon substrate isotropically, followed by anisotropic etching as desired, to achieve the resultant undulating, semi-corrugated sidewall profile and enhanced surface area characteristics of the present invention.

As mentioned previously, the methodology described above with respect to trench capacitors is equally applicable to the manufacture of stacked capacitors, also resulting in enhanced capacitance density characteristics. As in the process described above for a trench capacitor, in the manufacture of a stacked capacitor in accordance with the method of the present invention, a silicon substrate is first etched anisotropically, followed by isotropic etching (or vice versa) in iterative steps to achieve an undulating, semi-corrugated surface profile such as the surface profile 401 of FIG. 4. This structure can subsequently be processed to form a capacitor as is known in the art.

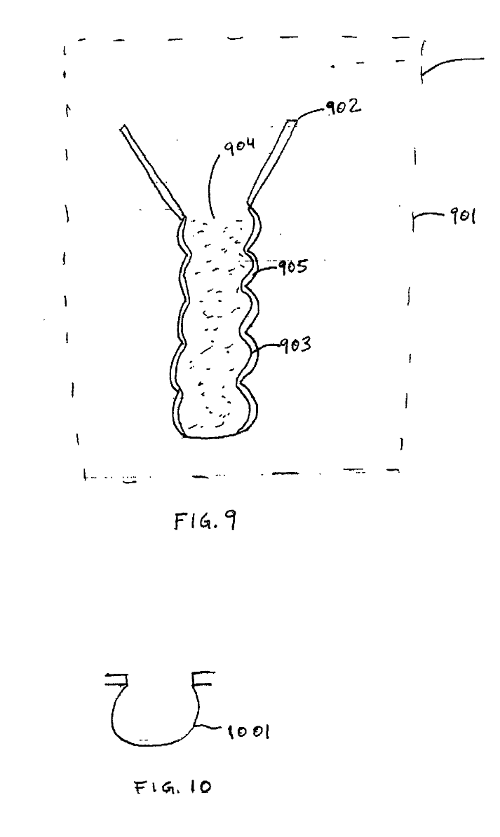

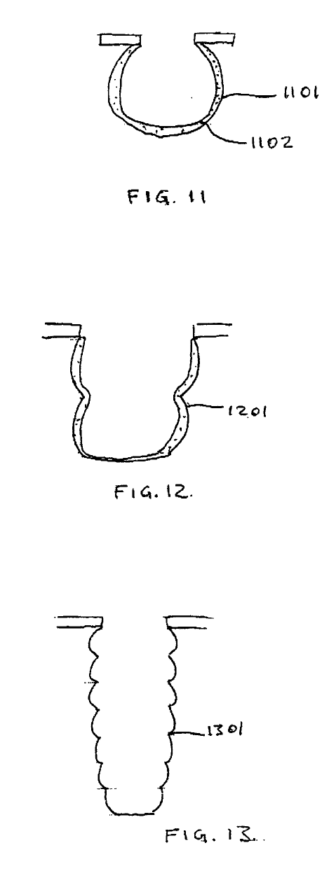

In a second embodiment of the present invention, the iterative process by which an undulating, semi-corrugated surface profile is achieved in the manufacture of trench and stacked capacitors is modified to comprise iterations of isotropic etching alternating with passivating deposition. According to one specific example, a substrate in preparation is first exposed to a plasma source gas appropriate for isotropic etching, for example, one comprising one of SF₆, Cl₂, NF₃, and CF₄, with SF₆ being a preferred choice. The use of SF₆ as a plasma source gas under the conditions described above with respect to the method of the first embodiment of the present invention generates a plasma that is highly isotropic in nature. FIG. 10 depicts a sidewall profile of a substrate after undergoing a single iteration of isotropic etching. As depicted therein, a balloon-shaped sidewall profile 1001 results from a period of isotropic etching. Following the predetermined period of isotropic etching, the plasma source gas introduced is changed to one having passivating deposition characteristics. In this embodiment, passivating source gases can be selected, for example, from any fluorocarbon or fluorohydrocarbon gas such as C₄F₈, CH₂F₂, CHF₃, and C₄F₆, with C₄F₈ being a preferred choice. Upon dissociation in the plasma, the C₄F₈ produces species which polymerize on the etched sidewall, preventing undercutting from continued isotropic etching and providing improved selectivity. For example, utilizing a system like that described above, C₄F₈ can be supplied from gas panel 138 to the process chamber 110 through inlets 126. For example, the C₄F₈ flow rate can be about 100 sccm. The gaseous mixture 150 is ignited into a plasma 152 in the process chamber 110 by applying RF power preferably in the region of 1000 W from the RF source generator 118 and 1 W from the RF bias generator 122. The pressure within the interior of the process chamber 110 is controlled between 10-200 mtorr and preferably in the region of 20 mtorr.

FIG. 11 depicts a sidewall profile 1101 of a substrate after an initial iteration of isotropic etching, followed by exposure to a passivating deposition gas. As is depicted therein, the deposition step provides a passivating deposition layer 1102 along the surface previously isotropically etched.

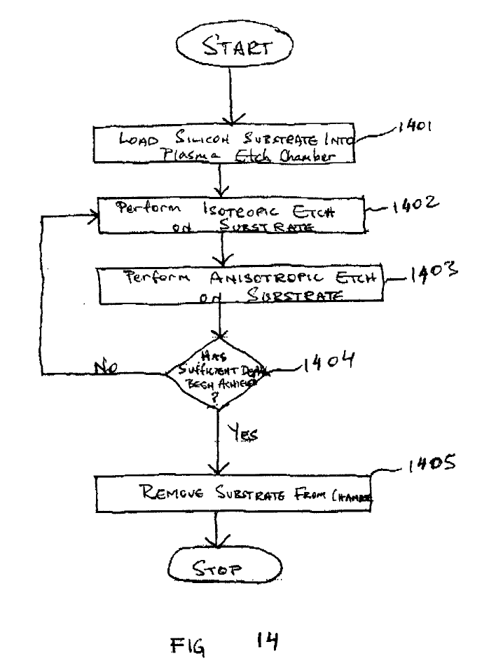

Once a passivating layer is deposited and with reference now to FIG. 12, another iteration of isotropic etching and deposition is performed resulting in the composite sidewall profile 1201. Due to the existence of a deposition layer from the previous step, the subsequent isotropic etch results in the extension of the previously etched sidewall profile into a second, contiguous, balloon-shaped sidewall profile, without substantially undercutting of the sidewall profile etched in the initial isotropic etch step. The alternating deposition and etch steps eventually result in a structure with the sidewall profile shown in FIG. 13. As depicted therein, after successive iterations of isotropic etching and deposition steps a trench capacitor structure is formed having a sidewall profile 1301.

It should be noted that while similar to the structure resulting from the iterative anisotropic/isotropic etch method of the first embodiment of the present invention, the structure resulting from the method of the present embodiment is characterized by the absence of the vertical shaft-like extensions between balloon like segments as depicted, for example, in profile 801 of FIG. 8. Instead, as can be seen from sidewall profile 1301 of FIG. 13, the balloon-like segments are directly linked in a “cloud” formation. Similar to the iterative anisotropic/isotropic etch method of the first embodiment, the method is readily applicable to the manufacture of stacked capacitors.

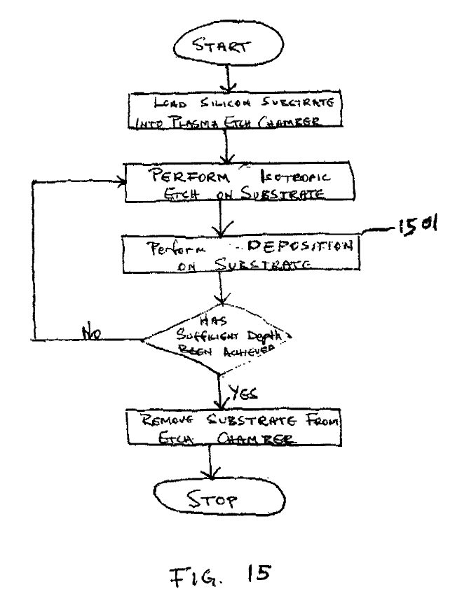

As has been demonstrated by the foregoing, the methods of both embodiments of the present invention are effective in increasing the capacitance density of trench and stacked capacitors without an increase in depth and aspect ratio. The methods of the two embodiments are comparatively illustrated in FIGS. 14 and 15. As depicted in FIG. 14, the method of the first embodiment of the present invention is characterized by loading a silicon substrate into a suitable process chamber such as that described in conjunction with FIG. 1 above. This step is illustrated by step 1401 of FIG. 14. Next, the substrate is etched isotropically as illustrated by step 1402. Following a period of isotropic etching, the substrate is then subjected to anisotropic etching as illustrated by step 1403. These two steps are iterated until a determination is made that the desired etch depth has been achieved. This decision step is illustrated by step 1404. When sufficient depth has been achieved, the iterative etch process is suspended and the substrate is removed from the process chamber (unless, of course, the same chamber is to be used for subsequent steps) as illustrated by step 1405. As noted above, the order of the isotropic and anisotropic etching steps can be reversed.

Similarly, in the second embodiment of the present invention, and as illustrated by FIG. 15, a substrate is etched iteratively to yield an undulating, semi-corrugated sidewall profile. However in accordance with the second embodiment, the iterative process is characterized by alternating an isotropic etch step with a step comprising the deposition of a passivating layer. This distinction is illustrated by step 1501 of FIG. 15 wherein in contrast to the process of the first embodiment of the present invention, a passivating layer is deposited on the substrate under preparation instead of performing an anisotropic etch step.

All the features disclosed in this specification (including any accompanying claims, abstract and drawings), and/or all of the steps or any method or process so disclosed, may be combined in any combination, except combinations where at least some of the features and or steps are mutually exclusive. Each feature disclosed in this specification (including any accompanying claims, abstract and drawings) may be replaced by alternative features serving the same equivalent or similar purpose, unless expressly stated otherwise. Thus unless expressly stated otherwise, each feature disclosed is one example only of a generic series of equivalent or similar features. Moreover, although various embodiments are specifically illustrated and described herein, it will be appreciated that modifications and variations of the invention are covered by the above teachings and within the purview of the appended claims without departing from the spirit and intended scope of the invention.

What is claimed is:

1. A method for etching a capacitor structure within a silicon substrate, said method comprising:
providing a masked substrate comprising a patterned masking layer over said silicon substrate, said patterned masking layer having at least one aperture formed therein;
performing a series of at least two process steps upon said masked substrate, said series of at least two process steps comprising an isotropic plasma etching step in which said silicon substrate is etched through said at least one aperture; and
repeating said series of at least two process steps until a desired etch depth for said capacitor structure is achieved, wherein said capacitor structure has etched sidewall with a undulating profile.

2. The method according to claim 1 wherein said capacitor structure ranges from 1-10.0 microns in vertical dimension.

3. The method according to claim 1, wherein said capacitor structure is a trench.

4. The method according to claim 1 wherein said capacitor structure is an elevated structure.

5. The method according to claim 1 wherein said series of at least two process steps comprises (1) an isotropic plasma-etching step and (2) an anisotropic plasma-etching step.

6. The method according to claim 1 wherein said series of at least two steps comprises (1) an isotropic plasma etching step and (2) a plasma deposition step in which a passivating layer is deposited on said substrate.

7. The method according to claim 5 wherein said isotropic etching step is performed in the presence of a source gas comprising one or more of SF₆, Cl₂, NF₃ and CF₄,

8. The method according to claim 7 wherein said isotropic etching step is performed in the presence of a source gas comprising SF₆.

9. The method according to claim 5 wherein said anisotropic etching step is performed in the presence of a plasma source gas comprising SF₆, HBr and O₂.

10. The method according to claim 9 wherein a SF₆:HBr:O₂ ratio is about 1:1:1.

11. The method according to claim 6 wherein said isotropic etching step is performed in the presence of a source gas comprising one or more of SF₆, Cl₂, NF₃ and CF₄.

12. The method according to claim 6 wherein said isotropic etching step is performed in the presence of a source gas comprising SF₆.

13. The method according to claim 6, wherein said deposition step is performed in the presence of a fluorocarbon gas or a fluorohydrocarbon gas.

14. The method according to claim 6, wherein said deposition step is performed in the presence of one or more of C₄F₈, CH₂F₂, CHF₃, and C₄F₆.

15. The method according to claim 6, wherein said deposition step is performed in the presence of C₄F₈.

16. The method according to claim 1 wherein said etching step is conducted at a plasma density ranging from 10¹¹ to 10¹² cm⁻³.

17. The method according to claim 1 wherein said etching step proceeds at a rate ranging from 1-3 microns per minute.

18. A capacitor structure formed by a process comprising:
providing a masked substrate comprising a patterned masking layer over said silicon substrate, said patterned masking layer having at least one aperture formed therein;
performing a series of at least two process steps upon said masked substrate, said series of at least two process steps comprising an isotropic plasma etching step in which said silicon substrate is etched through said at least one aperture; and
repeating said series of at least two process steps until a desired etch depth for said capacitor structure is achieved, wherein said capacitor structure has etched sidewall with a undulating profile.

19. The capacitor structure according to claim 18, wherein said capacitor structure ranges from 1-10.0 microns in vertical dimension.

20. The capacitor structure according to claim 18, wherein said capacitor structure is a trench.

21. The capacitor structure according to claim 18, wherein said capacitor structure is one of a portion of a stacked capacitor and a trench capacitor.

22. The capacitor structure according to claim 18, wherein said series of at least two process steps comprises (1) an anisotropic plasma-etching step and (2) an isotropic plasma-etching step.

23. The capacitor structure according to claim 18 wherein said series of at least two process steps comprises (1) an isotropic plasma etching step and (2) a plasma deposition step in which a passivating layer is deposed on said substrate.
